(19) United States
(12) Patent Application Publication
(10) Pub. No.: US 2025/0365928 A1
(43) Pub. Date: Nov. 27, 2025

(54) Memory Circuitry And Methods Used In Forming Memory Circuitry

(71) Applicant: Micron Technology, Inc., Boise, ID (US)

(72) Inventors: Yuanzhi Ma, Meridian, ID (US); Si-Woo Lee, Saratoga, CA (US); Scott E. Sills, Boise, ID (US)

(73) Assignee: Micron Technology, Inc., Boise, ID (US)

(21) Appl. No.: 19/186,316

(22) Filed: Apr. 22, 2025

Related U.S. Application Data
(60) Provisional application No. 63/650,268, filed on May 21, 2024.

(51) Int. Cl. H10B 12/00

(52) U.S. Cl. CPC H10B 12/31; H10B 12/0335; H10B 12/09; H10B 12/50

(57) ABSTRACT

Memory circuitry comprises vertically-stacked memory cells individually comprising a horizontal transistor and a capacitor electrically coupled therewith. A storage-node electrode of the capacitor comprises a mid-portion on and about an axis, an overlying portion (comprising an upper annulus) directly electrically coupled with and directly above the mid-portion. An underlying portion (comprising a lower annulus) is directly electrically coupled with and directly below the mid-portion. The common electrode of the capacitor in the vertical cross-section comprises an upper portion inside the upper annulus and a lower portion inside the lower annulus. Other aspects and embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-10 and 48 are diagrammatic sectional views of constructions in accordance with embodiments of the invention.

FIGS. 11-47 are diagrammatic sequential sectional and/or enlarged views of the construction of FIGS. 3-10, or portions thereof or alternate and/or additional embodiments, in process in accordance with some embodiments of the invention.

### DETAILED DESCRIPTION OF EXAMPLE EMBODIMENTS

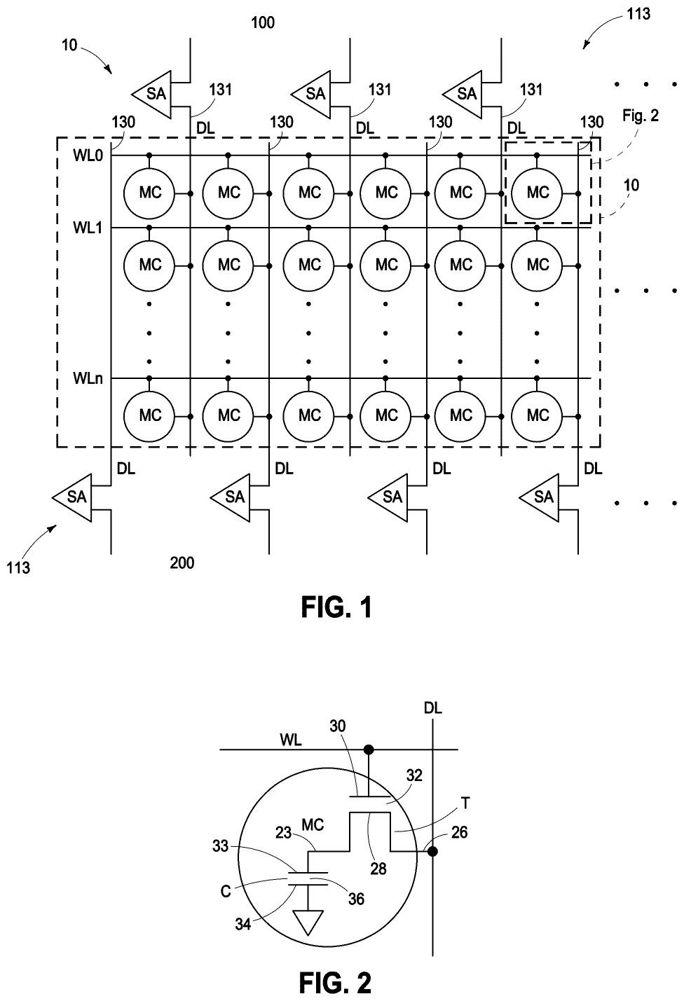

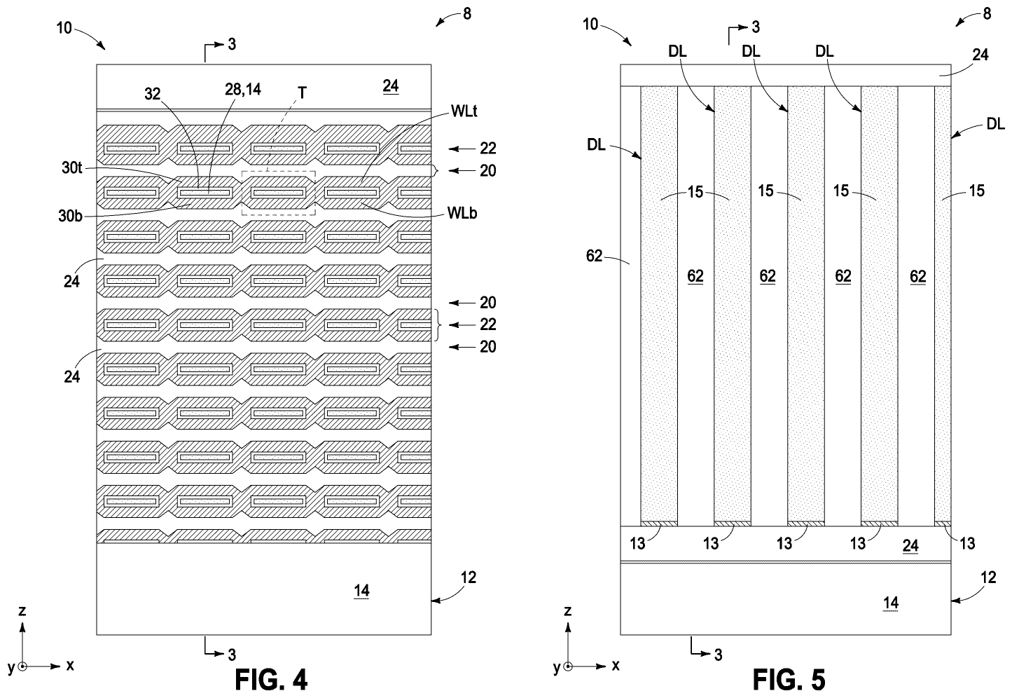

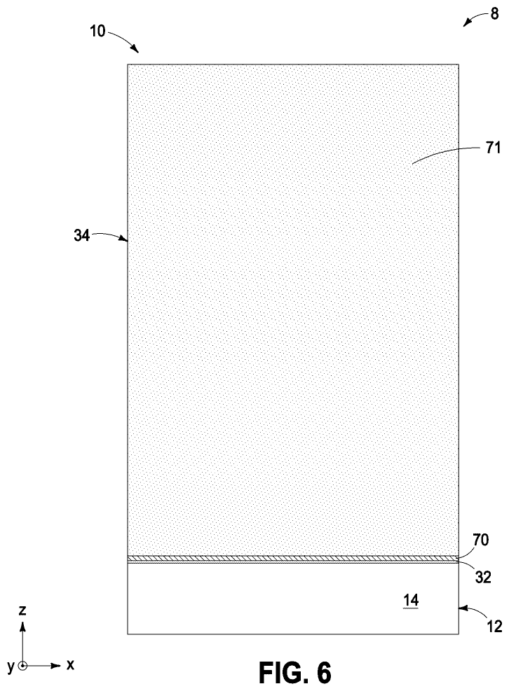

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-10.

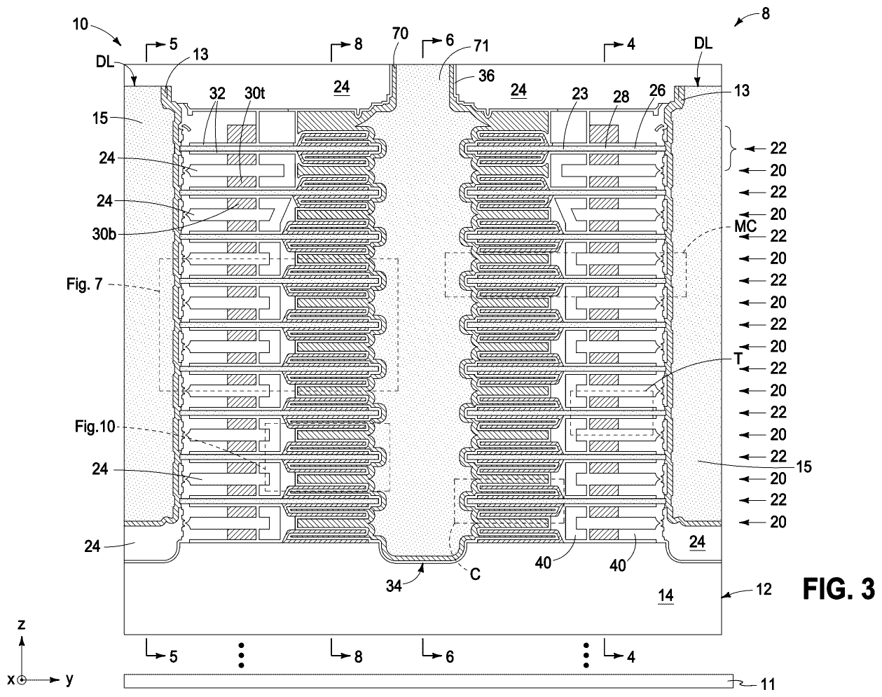

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line W L. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Non-schematic structure embodiments as shown herein in FIGS. 3+have the wordlines/access lines running horizontally and the digitlines/sense lines running vertically. Further, and by way of example only, sense amps SA could be on only one side or all directly above or directly below memory array area 10.

Referring to FIG. 3-10, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-10-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Example memory circuitry (e.g., that of or comprising construction 8) comprises vertically-alternating tiers 20, 22 (e.g., along example direction z) of insulative material 24 (e.g., silicon dioxide and/or silicon nitride) and vertically-stacked memory cells M C, respectively. Example construction 8 comprises a semiconductor substrate 12 (e.g., a bulk wafer comprising monocrystalline silicon 14) above which tiers 20 and 22 are received. Regardless, memory cells MC individually comprise a horizontal transistor T, for example comprising a first source/drain region 23, a second source/drain region 26, and a channel region 28 horizontally between the first and second source/drain regions. Regions 23, 26, and 28 of different immediately-horizontally-adjacent memory cells M C into and out of the plane of the page upon which FIG. 3 lies in a common memory-cell tier 22 may be isolated relative one another by insulative material (not shown). Transistor T also comprises a gate 30* (e.g., gate-all-around the channel; e.g., conductive metal material) having a gate insulator 32 (e.g., dielectric or ferroelectric) between at least channel region 28 and gate 30* (an * being used as a suffix to be inclusive of all such same-numerically-designated structures or portions thereof that may or may not have other suffixes). Gate 30* comprises part of a one of a plurality of horizontal conductive access lines W L* that individually directly electrically couple together multiple gates 30* of different ones of horizontal transistors T that are in the same memory-cell tier 22. An example insulator material 40 (e.g., silicon nitride) is laterally proximate lateral sides/edges of gates 30*. In one embodiment and as shown, gate 30* comprises part of a top gate 30t that is part of a top access line W Lt and comprises part of a bottom gate 30b that is part of a bottom access line WLb.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells M C, and a capacitor insulator 36 there-between (e.g., dielectric or ferroelectric). Storage-node electrode 33 is directly coupled to first source/drain region 23 of transistor T. Digitlines DL (e.g., comprising conductive materials 13 and 15) extend through vertically-alternating tiers 20 and 22. Digitlines DL of different immediately-horizontally-adjacent memory cells M C into and out of the plane of the page upon which FIG. 3 lies in a common memory-cell tier 22 may be isolated relative one another by insulative material 62 (e.g., silicon dioxide and/or silicon nitride). Individual second source/drain regions 26 of individual transistors T that are in different memory-cell tiers 22 are directly electrically coupled to individual digitlines DL. Capacitor C and horizontal transistor T may be considered as being horizontally spaced relative one another along an axis 80 (i.e., a straight-line and that is not necessarily central relative to either but is as shown; e.g., along example direction y).

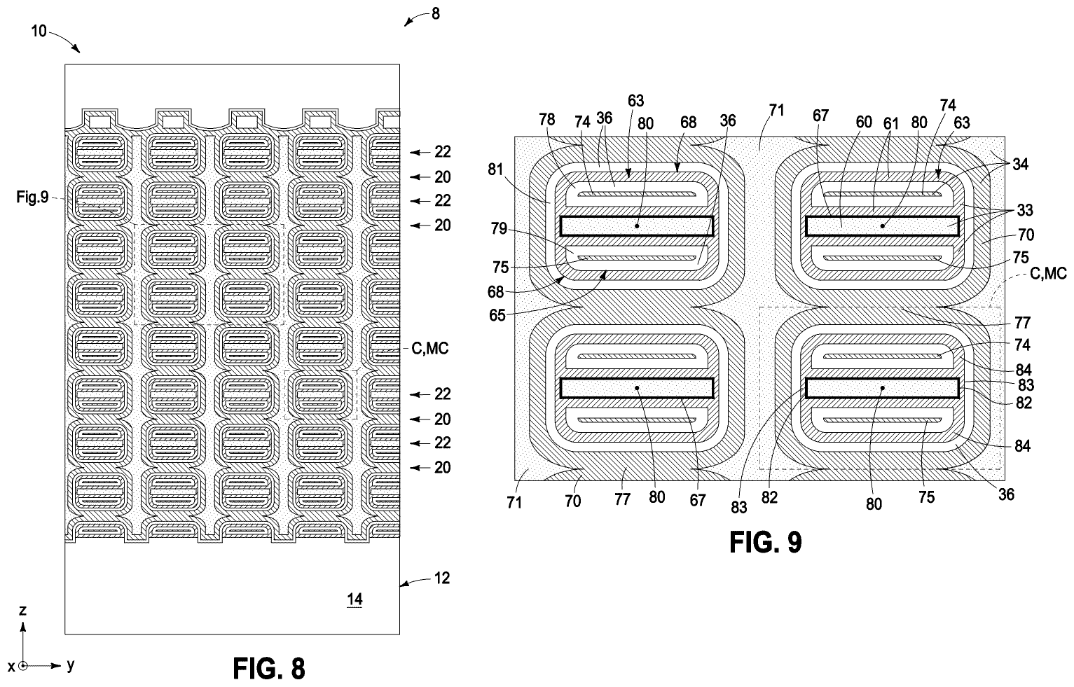

Capacitor storage-node electrode 33 comprises a mid-portion 60 on and about axis 80 (e.g., conductively-doped semiconductor material, such as conductively-doped monocrystalline or polycrystalline silicon). M id-portion 60 in some embodiments may be considered as comprising an end 66, in some embodiments referred to as a mid-end 66 or mid-portion end 66, on axis 80. An overlying portion 61 (e.g., conductive metal material) of storage-node electrode 33 is directly electrically coupled with and directly above mid-portion 60. Overlying portion 61 comprises an upper annulus 63 in a vertical cross-section that is horizontally-elongated orthogonal to the axis (e.g., the vertical cross-section that is FIG. 8 or 9; e.g., along example direction x). An underlying portion 64 of storage-node electrode 33 is directly electrically coupled with and directly below mid-portion 60. Underlying portion 64 comprises a lower annulus 65 in the vertical cross-section.

In one embodiment, overlying portion 61 and underlying portion 64 individually comprise a sideways container 68 that faces horizontally away from horizontal transistor T in a vertical cross-section that is through and horizontally-elongated along axis 80 (e.g., the vertical cross-section that is FIG. 3, 7, or 10). Overlying portion 61 has a lowest far-end 72 (“far” being relative to distance from horizontal transistor T) that is directly above axis 80 and underlying portion 64 has an uppermost far-end 73 that is directly above axis 80. Lowest and uppermost far-ends 72 and 73, respectively, are laterally-spaced from mid-end 66 towards horizontal transistor T.

In one embodiment, mid-portion 60 comprises a conductive metal silicide 67 there-atop (e.g., shown as a thick, bold line; e.g., W Six) and there-below and that are respectively directly against overlying portion 61 and underlying portion 64 (and that may alternately be considered as portions thereof instead of part of mid-portion 60). In one such embodiment and as shown, conductive metal silicide 67 is laterally over and aside mid-portion end 66.

Common electrode 34 in the vertical cross-section of FIG. 8 or 9 comprises an upper portion 74 inside upper annulus 63 and a lower portion 75 inside lower annulus 65. In one embodiment, common electrode 34 comprises an intervening portion 77 that is vertically between immediately-vertically-adjacent memory cells M C (i.e., there being no other memory cell that is vertically between those that are immediately-vertically-adjacent one another).

Capacitor insulator 36 in the vertical cross-section of FIG. 8 or 9 comprises an upper ring 78 inside upper annulus 63 and about (circumferentially around) upper portion 74 and a lower ring 79 inside lower annulus 65 and about lower portion 75. Capacitor insulator 36 also comprises an outer ring 81 collectively about upper annulus 63, lower annulus 65, mid-portion 60, upper ring 78, upper portion 74, lower ring 79, and the lower portion 75. As used herein, “ring” and “annulus” are synonymous with one another and used collectively for distinguishing language in the claims. Such may be circular, non-circular, a combination of differently curved and/or different length segments, a combination of straight and/or different length segments, a combination of curved and straight segments, etc. Regardless, and in one embodiment and as shown, capacitor insulator 36 is vertically between intervening portion 77 and each of (a) and (b), where:
(a): underlying portion 64 of an upper of immediately-vertically-adjacent memory cells M C; and
(b): overlying portion 61 of a lower of immediately-vertically-adjacent memory cells M C.

In one embodiment, in the vertical cross-section of FIG. 8 or 9, mid-portion 60 has laterally-opposing edges 82, with conductive material 83 being included and that is contiguous with conducting material 84 of upper and lower annuli 63 and 65, respectively, and extends laterally over and aside edges 82. In one embodiment, capacitor insulator 36 is laterally over and aside end 66 and, in one such embodiment, common electrode 34 is laterally over and aside end 66 with capacitor insulator 36 being laterally between end 66 and common electrode 34.

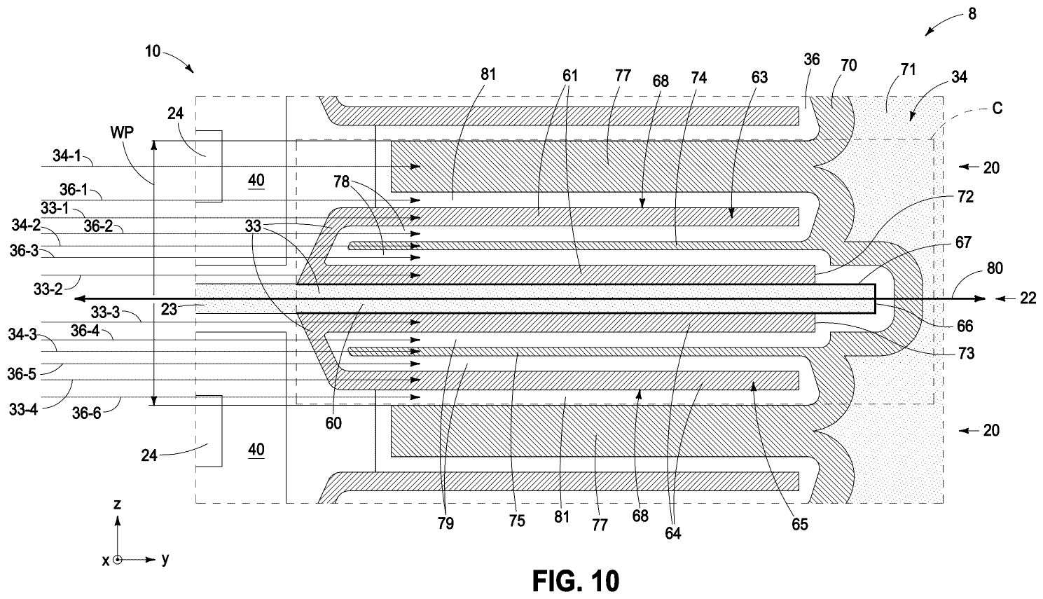

FIG. 10 shows capacitors C having a vertical pitch VP having three layers of common electrode 34-1, 34-2, and 34-3, six layers of capacitor insulator 36-1, 36-2, 36-3, 36-4, 36-5, and 36-6, and four layers of storage-node electrode 33-1, 33-2, 33-3, and 33-4 (in addition to mid-portion 60).

Any other attribute(s) or aspect(s) as shown and/or described herein with respect to other embodiments may be used in the embodiments shown and described with reference to the above embodiments.

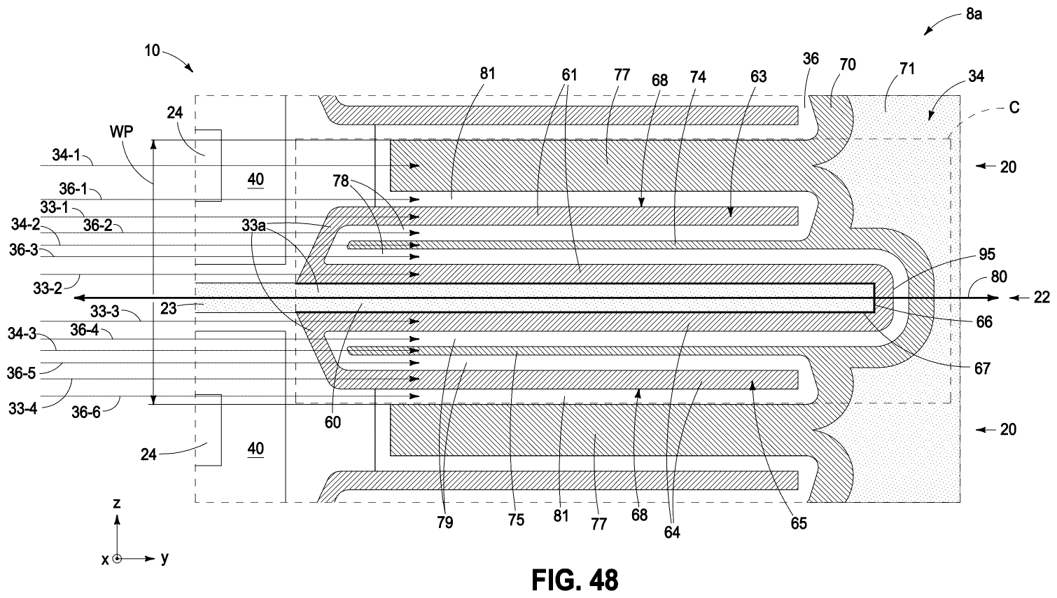

An alternate example embodiment and construction 8a is shown in FIG. 48. Like numerals from the above-described embodiments have been used where appropriate, with some construction differences being indicated with the suffix “a” or with different numerals. In example construction 8a, storage-node electrode 33a comprises a connecting portion 95 laterally over and aside end 66 in a vertical cross-section that is through and horizontally-elongated along axis 80 (e.g., that of FIG. 48), with connecting portion 95 being contiguous with overlying and underlying portions 61 and 64, respectively. Capacitor insulator 36 is laterally between connecting portion 95 and common electrode 34. Any other attribute(s) or aspect(s) as shown and/or described herein with respect to other embodiments may be used.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

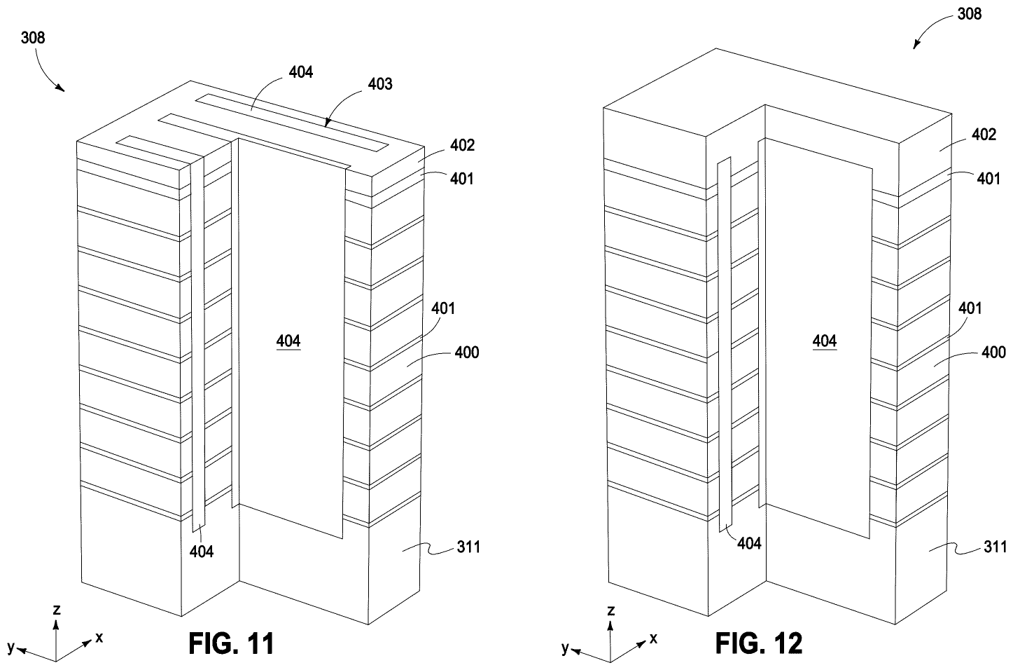

FIGS. 11-47 by way of example sequentially show predecessor constructions in an example method used in forming memory circuitry. Such memory circuitry ultimately comprises vertically-stacked memory cells individually comprising a horizontal transistor and a capacitor electrically coupled (e.g., directly) therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. Such memory circuitry may comprise structural embodiments of the invention as described above with respect to FIGS. 1-10 and 48.

FIGS. 11-47 show orientation relative to x, y, and z directions, with some aspects shown with cut planes (e.g., along xz-planes and along yz-planes) to show some embedded features. The artisan will recognize that operations illustrated in and described with reference to FIGS. 11-47 can be performed by manufacturing systems, such as a semiconductor fabrication systems, configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the various shown features. For brevity, not all operations are described, such as those that would be recognized by the artisan as may being conducted where desired or necessary (e.g., some doping of semiconductor materials with conductivity enhancing dopants during and/or after deposition to achieve desired conductivity/semiconductivity, annealings, etc.). Further, some methods, techniques, processes, and operations may be performed in different orders, or at different times, or otherwise modified. Further, some operations may be omitted from the described fabrication operations, or other operations may be added to the described fabrication operations. Also, the artisan will appreciate that other materials and/or structures may be used than those specifically referred to below depending on application, whether such are temporary and/or remain in the finished construction, what is or is not being selectively etched relative to what, etc., with those provided below being examples only.

Referring to FIG. 11, construction 308 comprises a bulk monocrystalline silicon substrate 311 having a stack of vertically-alternating layers comprising silicon material 400 (e.g., elemental monocrystalline or polycrystalline silicon and which may include one or more additional elements) and silicon-germanium material 401 (e.g., Si₁₋ₓGeₓ and which may include one or more additional elements) formed there-above. Silicon-material layers 400 will comprise part of horizontal transistors and capacitors in a finished construction of the memory circuitry. A silicon oxycarbide hardmask material 402 has been formed there-atop. Trenches 403 horizontally-elongated in x have been formed, filled with carbon 404, and carbon 404 polished back to the top of hardmask material 402. Additional hardmask material 402 has been formed there-atop as shown in FIG. 12.

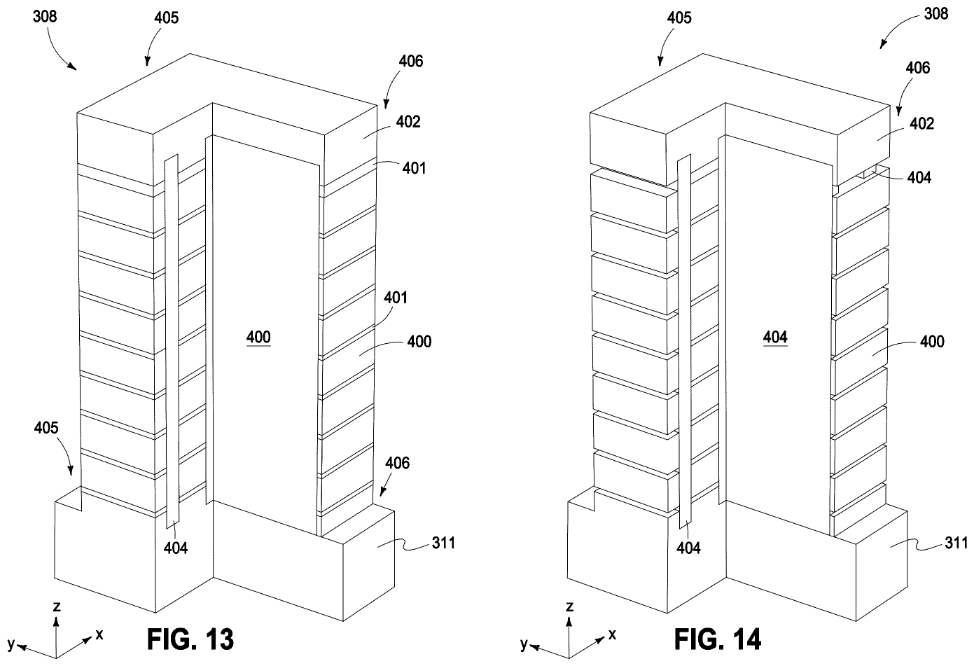

FIG. 13 shows formation of trenches 405 horizontally-elongated in x on what will be the wordline side and trenches 406 horizontally-elongated in x on what will be the capacitor side. FIG. 14 shows etching of silicon-germanium material 401 (no longer shown) selectively relative to silicon 400.

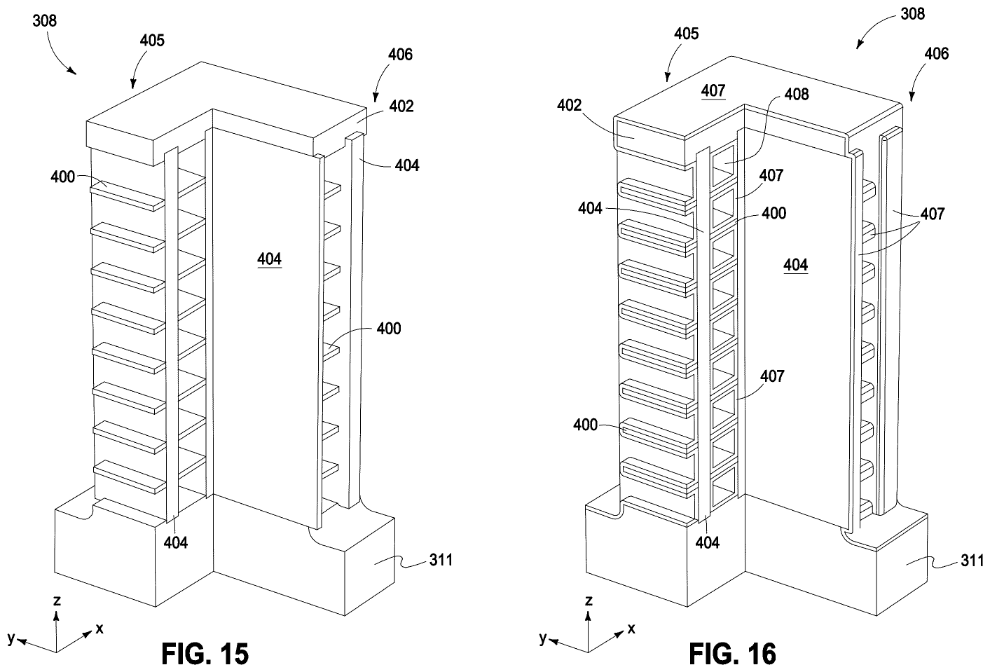

FIG. 15 shows etching of silicon 400 selectively relative to carbon 404 and hardmask material 402 to thin silicon 400 to at or near the final thickness of components 26, 28, 23, and 60 in the described example structure embodiments.

FIG. 16 shows formation of a thin liner of silicon nitride 407 to leave void spaces 408 as shown.

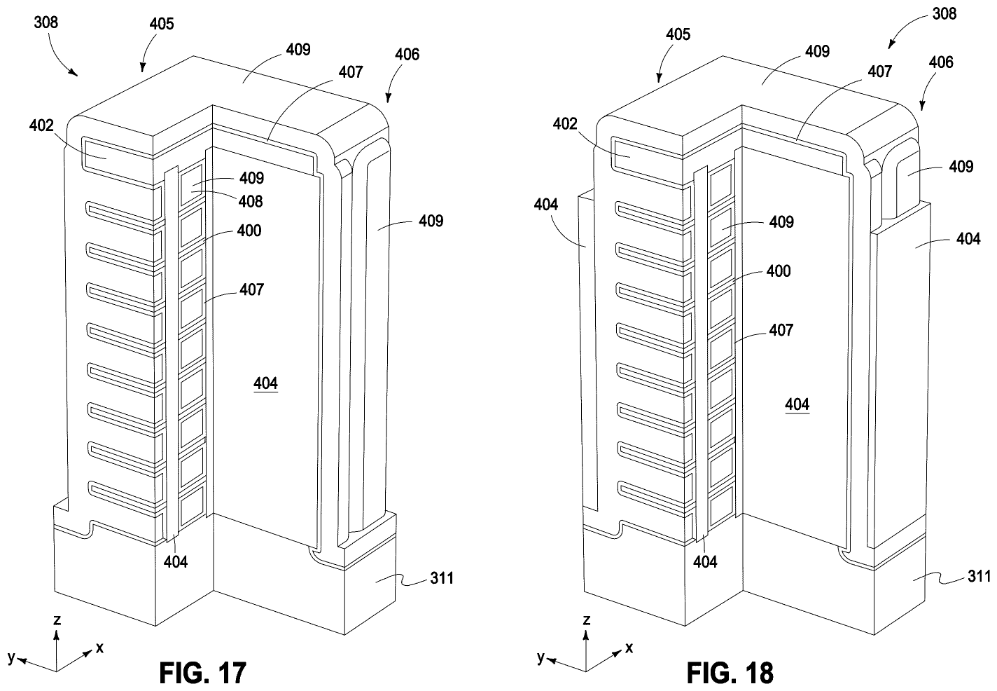

FIG. 17 shows formation of silicon dioxide 409 that fills void spaces 408. FIG. 18 shows formation of more carbon 404 within trenches 405 and 406 followed by vertical recessing thereof.

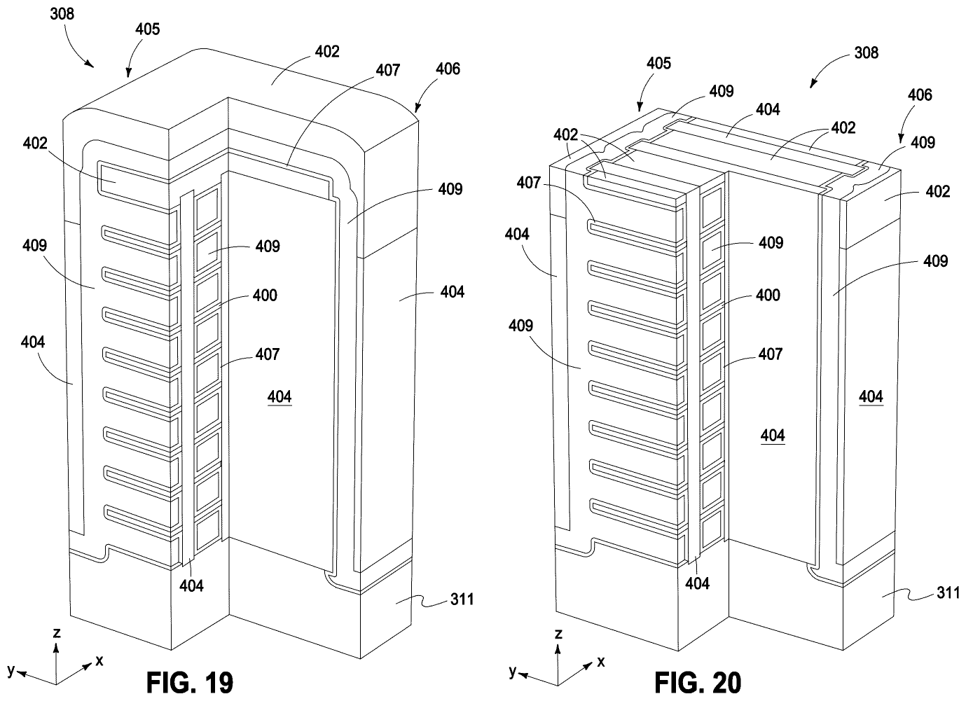

FIG. 19 shows formation of more hardmask material 402 to isolate trench carbon 404 from downstream processing. FIG. 20 shows removing sufficient hardmask material 402 to expose more silicon dioxide 409.

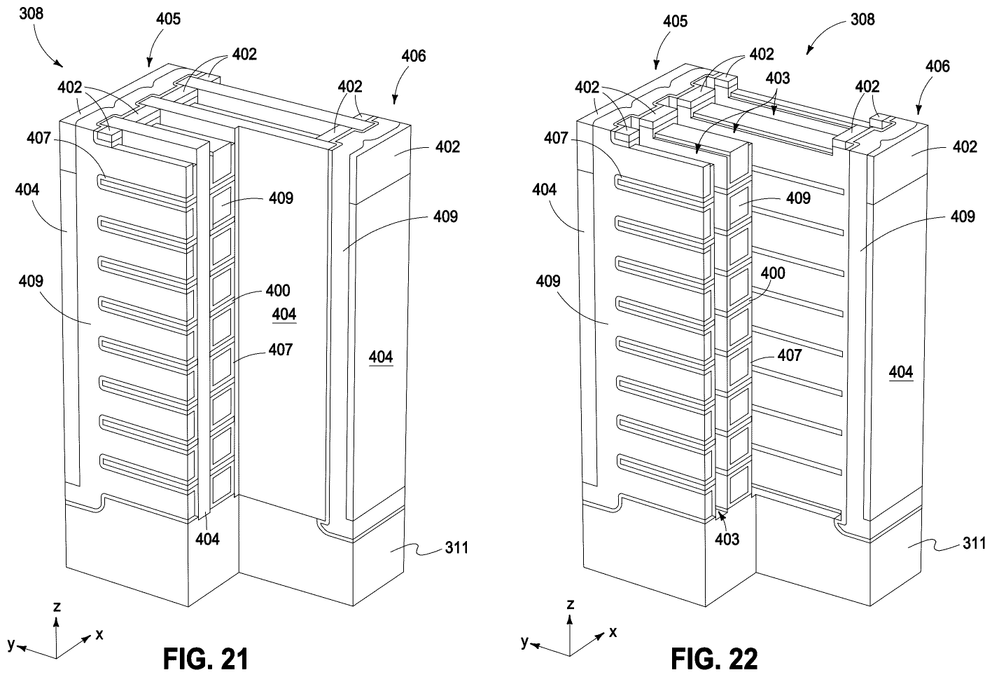

FIG. 21 shows recessing of hardmask material 402 and some of silicon nitride 407 (e.g., using a mask that is not shown) to expose silicon dioxide 409.

FIG. 22 shows removal of carbon 404, for example by an oxygen stripping process.

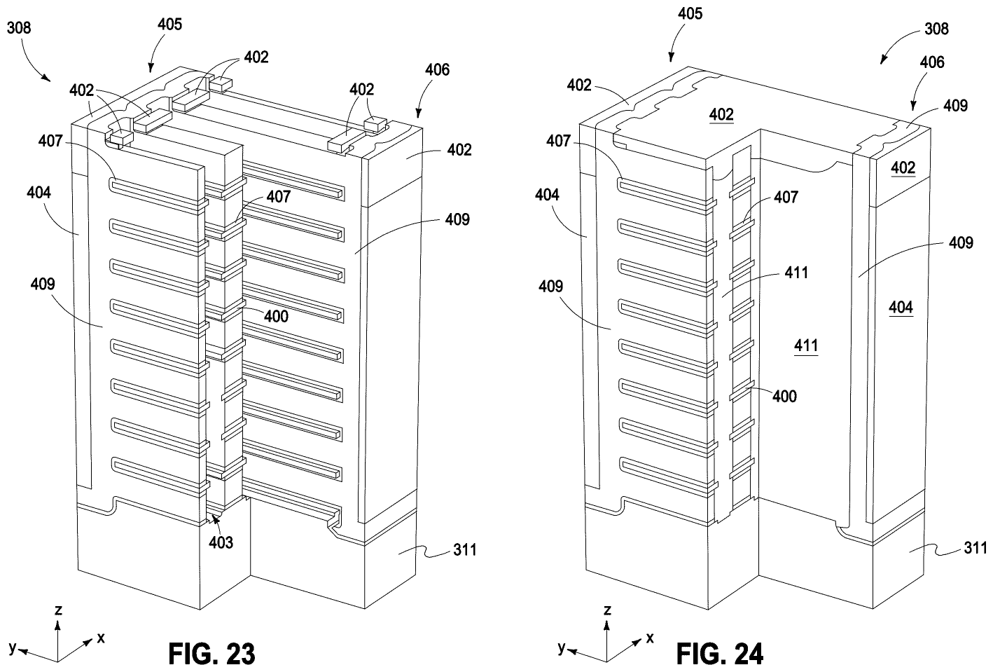

FIG. 23 shows removal of some of silicon nitride 407 to produce the depicted construction (e.g., to remove the vertically-elongated portions thereof).

FIG. 24 shows filling of the depicted remaining volume of trenches 403 with silicon-germanium 411, etching such back slightly, and followed by deposition of more hardmask material 402 and planarizing such back as shown.

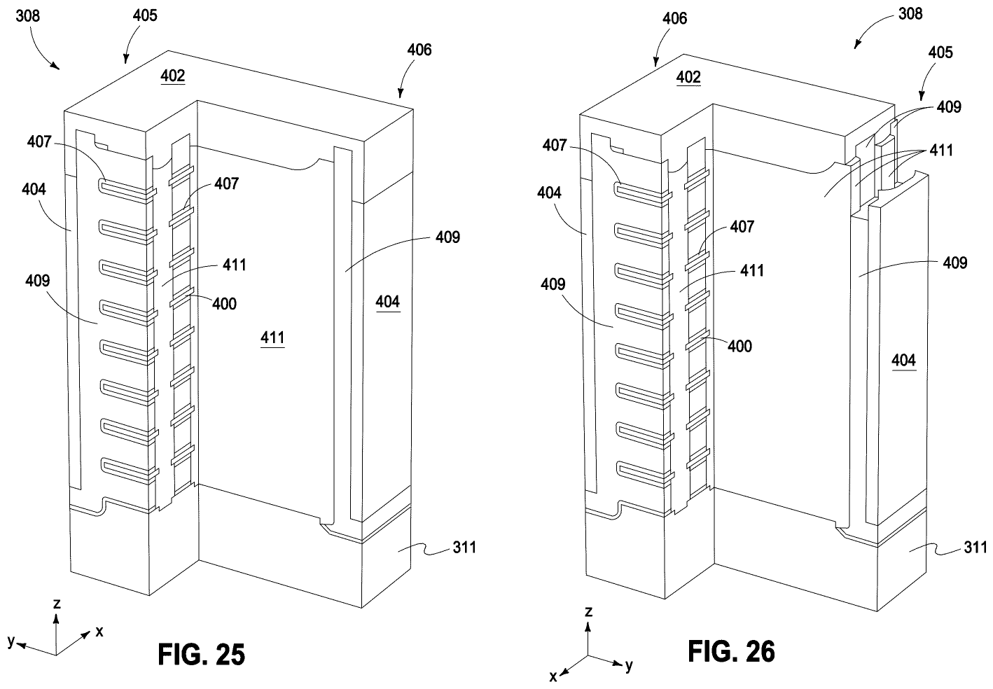

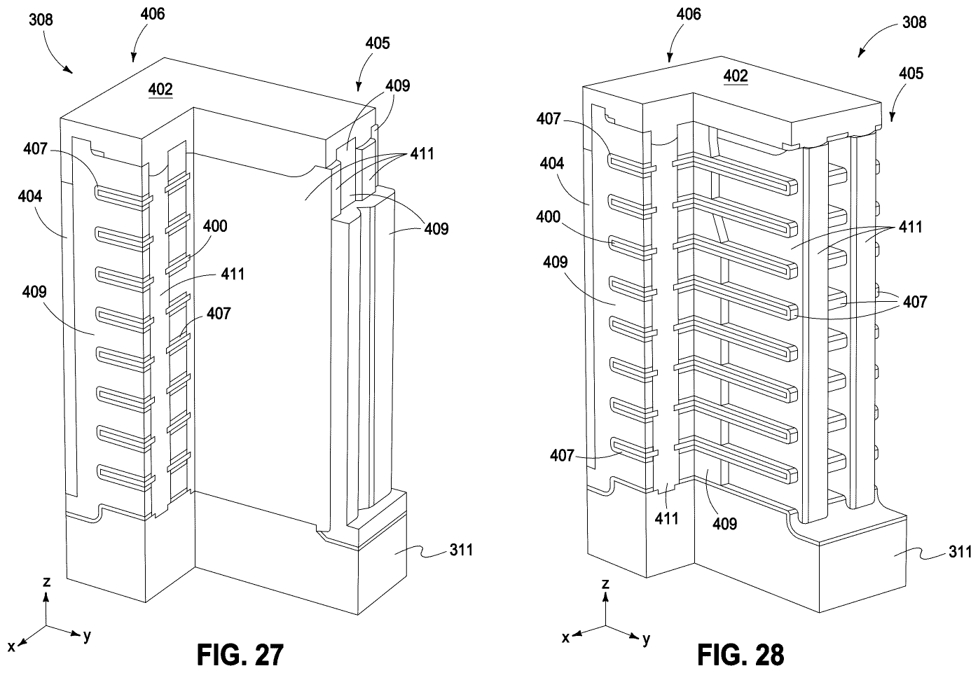

FIG. 25 shows formation of more hardmask material 402 and FIG. 26 shows patterning thereof to open such on the wordline side. Note that FIG. 26, as well as FIGS. 27-35, have been rotated relative to FIGS. 11-25, now showing construction 308 from the wordline side as opposed to the capacitor side.

FIG. 27 shows stripping of carbon 404 from wordline-side trenches 405. FIG. 28 shows horizontal recessing of silicon dioxide 409 selectively relative to silicon-germanium material 411.

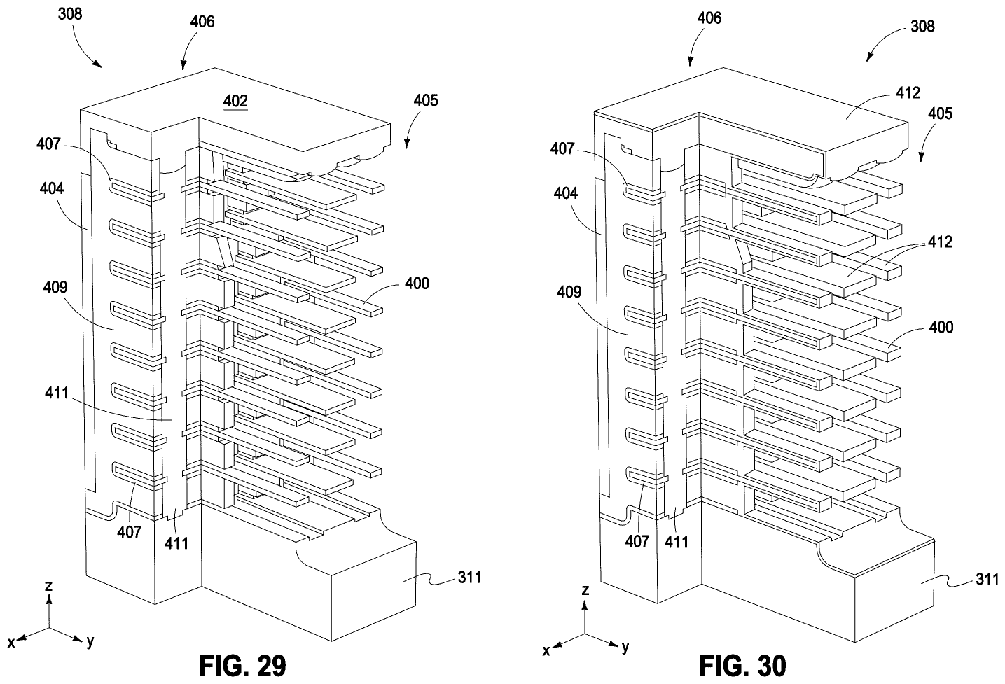

FIG. 29 shows removal of some silicon-germanium material 411 and FIG. 30 shows formation of a thin protective silicon dioxide or silicon oxycarbide liner 412.

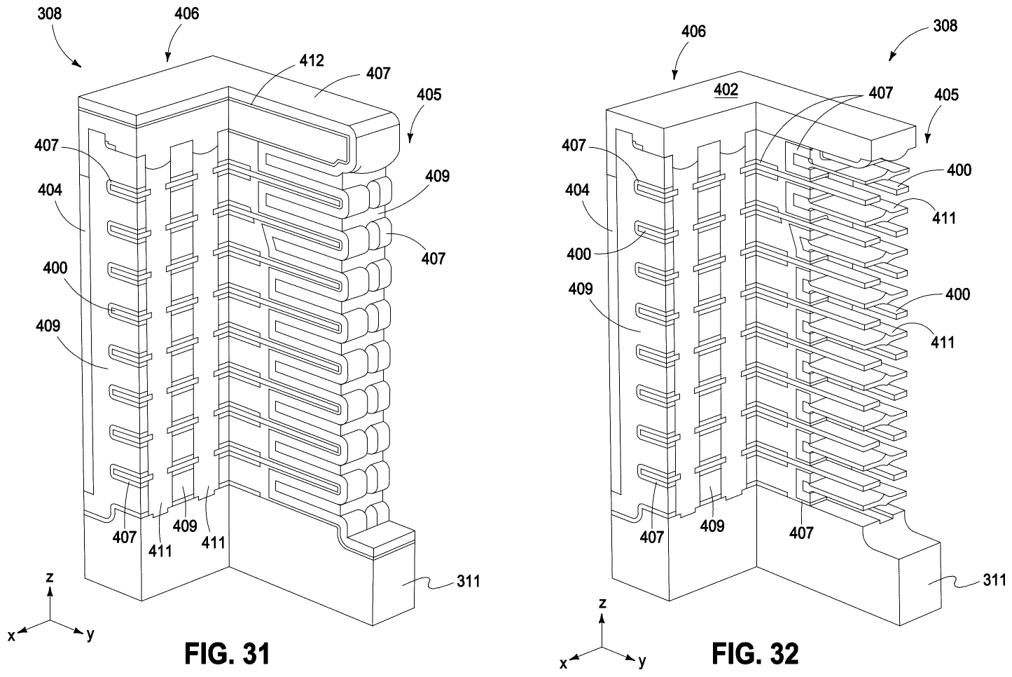

FIG. 31 shows formation of a liner of silicon nitride 407, followed by forming more silicon dioxide 409, and followed by laterally recessing such within wordline-side trenches 405 to expose the liner of silicon nitride 407. FIG. 32 shows lateral etch-back of silicon nitride liner 407 followed by removal of protective liner 412 to expose silicon material 400 (e.g., if liner 412 is silicon oxycarbide, by oxidizing such to SiO₂ and then removing such SiO₂).

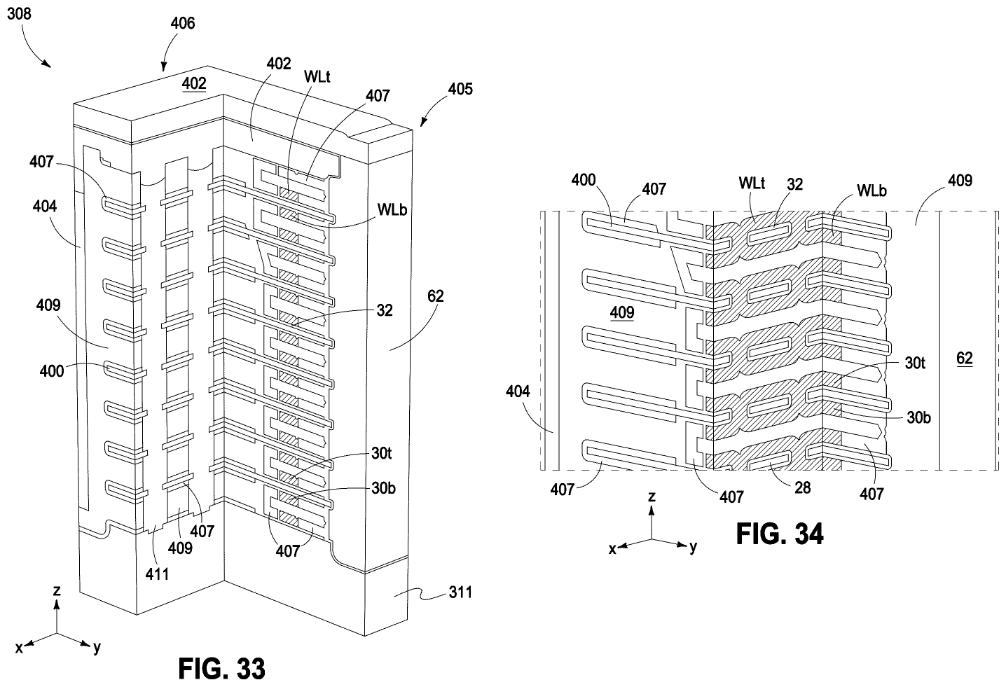

FIGS. 33 and 34 show formation of suitable gate insulator 32, then conductive material followed by lateral recessing thereof to form wordlines W Lt and WLb, followed by forming more silicon nitride 407 and silicon dioxide 62.

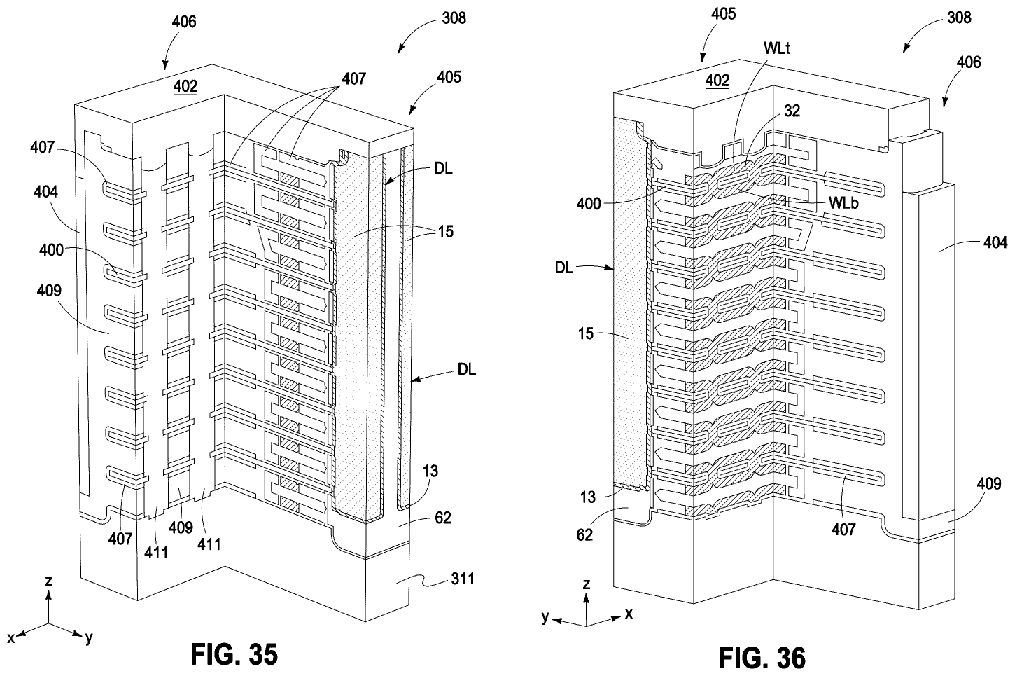

FIG. 35 shows formation of digitlines DL. Suitable doping of regions of silicon material 400 could occur where desired to achieve desired conductivity degree and type. Hardmask material 402 has thereafter been deposited to largely protect the wordline side from processing associated with the capacitor side.

FIG. 36, again now looking from the capacitor side, shows hardmask material 402 as having been opened/etched over capacitor-side trenches 406 to expose carbon 404 therein.

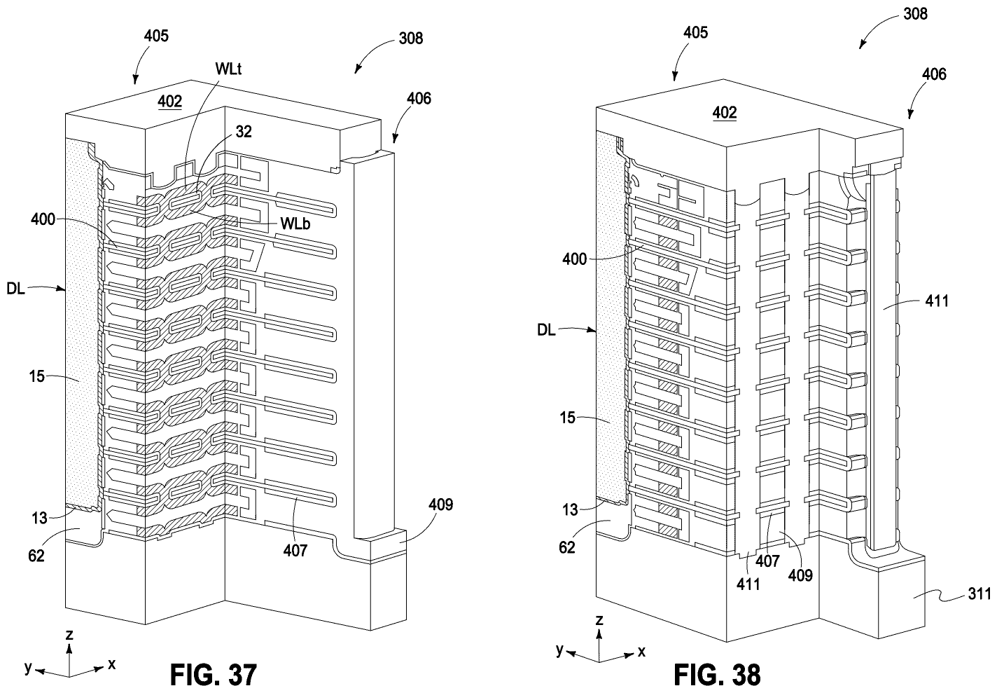

FIG. 37 shows removal of carbon 404 from capacitor-side trenches 406 (such carbon 404 thereby no longer being shown). FIG. 38 shows etching of silicon dioxide 409 selectively relative to silicon-germanium material 411 to expose silicon nitride 407.

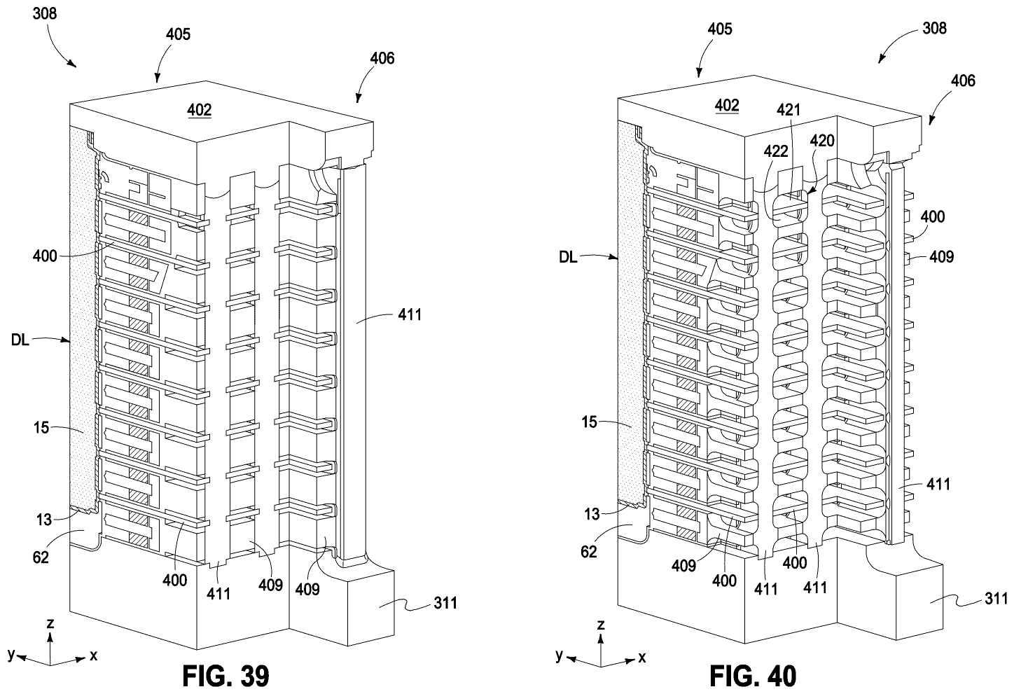

FIG. 39 shows selective etching of silicon nitride 407 relative to silicon-germanium material 411, silicon dioxide 409, and silicon 400.

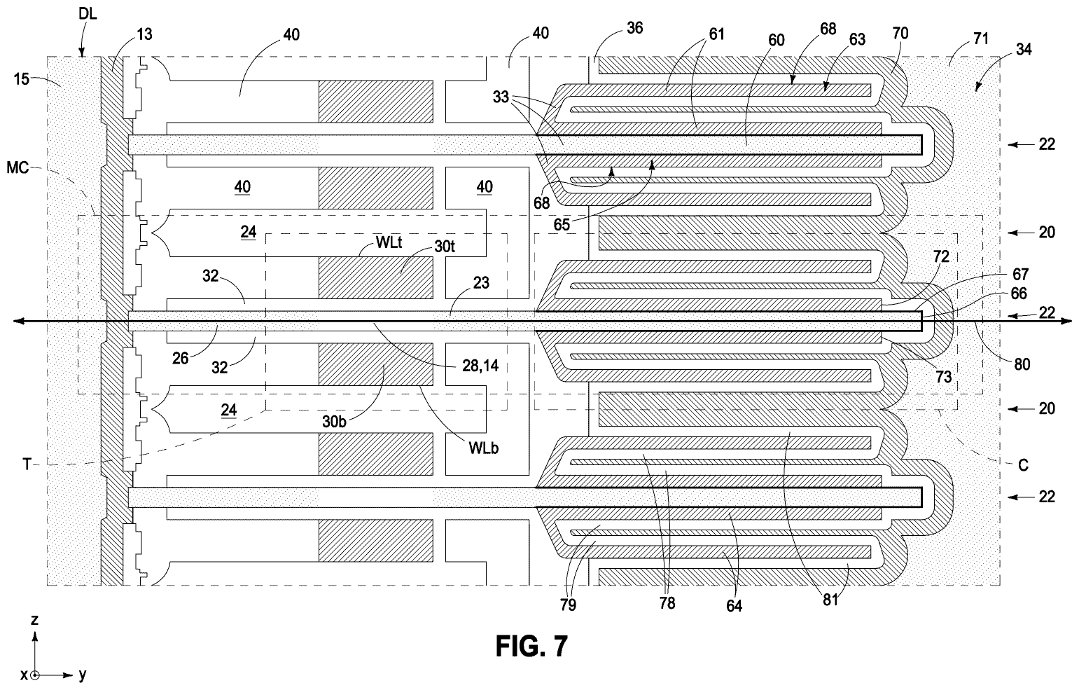

FIG. 40 shows subsequent etching of silicon-germanium material 401 and silicon dioxide 409 selectively relative to silicon 400 (e.g., together or separately) to enlarge the depicted void space that was formed in FIG. 39 by the removal of some of silicon nitride 407. Silicon material 400 as shown in FIG. 40 may be considered as mid-portion material 60 (FIGS. 7, 9, and 10) of a storage node electrode 33 (in fabrication) that is on and about axis 80 (FIGS. 7, 9, and 10) within a cavity 420 that is in surrounding sacrificial material (e.g., that is encompassed by some of silicon-germanium material 411 and some of silicon dioxide 409). Cavity 420 may be considered as comprising an upper part 421 that is directly above mid-portion material 60 and a lower part 422 that is directly below mid-portion material 60. Conductive doping of silicon 400/mid-portion material 60 may occur, for example, after the processing shown by FIG. 40, as may formation of silicide 67 (not shown in FIG. 40; e.g., by elemental metal deposition onto silicon 400 followed by anneal) as shown in FIGS. 7, 9, and 10. Such silicide might also be formed, for example as described below. All the above processing shown and described relative to FIGS. 11-40 is but one example method of forming such a described construction.

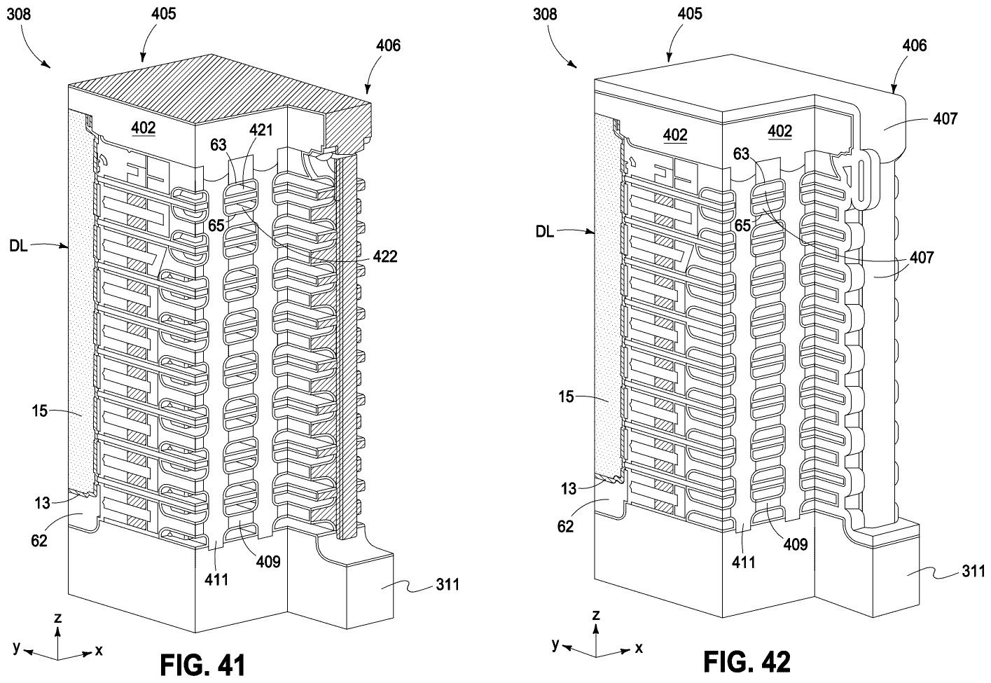

FIG. 41 shows conductive material (e.g., TiN) as having been deposited and thereby forming a conductive upper annulus 63 in upper part 421 of cavity 420 directly against mid-portion material 60 and a conductive lower annulus 65 in lower part 422 of cavity 420 directly against mid-portion material 60. In one embodiment, mid-portion material 60 may be considered as having laterally-opposing edges 82 (FIG. 9) within cavity 420, with conductive material of upper and lower annuli 63, 65 being formed to extend laterally over and aside edges 82 (FIG. 9) when forming upper and lower annuli 63, 65. In one embodiment, mid-portion material 60 at least predominantly (more than 50% up to and including 100%) comprises silicon, with the forming of upper and lower annuli 63, 65 comprising forming conductive metal-material in upper and lower parts 421, 422 of cavity 420 directly against the silicon, plus annealing such conductive metal-material and silicon to form a conductive metal silicide (e.g., 67 in FIGS. 7, 9, and 10) directly against the silicon. Such metal silicide may also form laterally aside and directly against the silicon on end 66 (e.g., 67 in FIGS. 7, 9, and 10) and laterally over and aside edges 82 (FIG. 9).

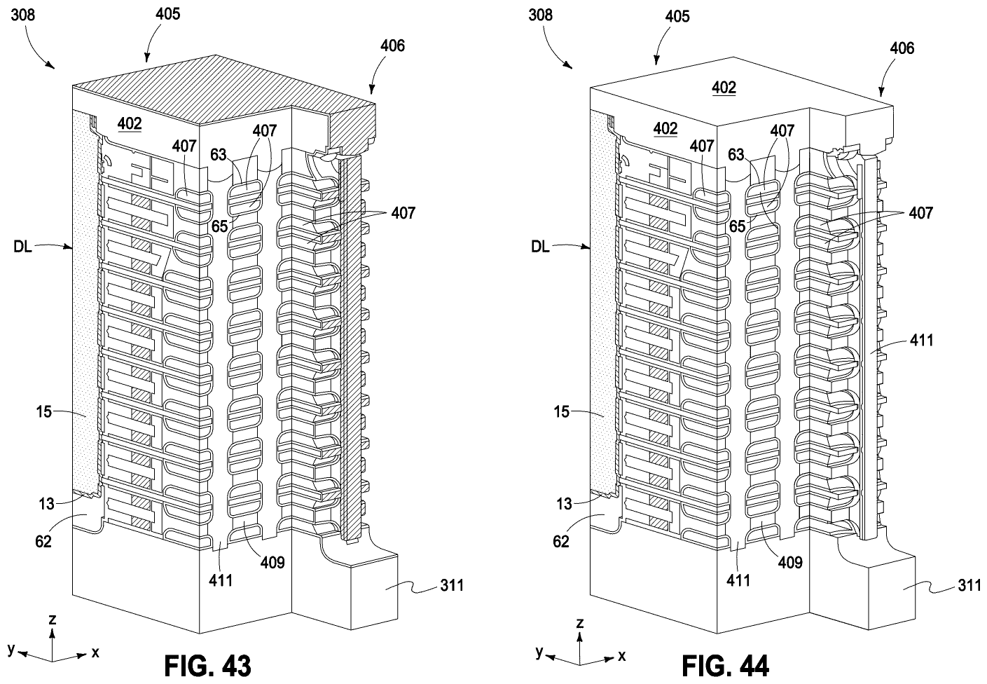

FIG. 42 shows filling of remaining void space with sacrificial silicon nitride 407. FIG. 43 shows recessing silicon nitride 407 to expose conductive upper and lower annuli 63, 65, respectively. FIG. 44 shows removing some of the material of conductive upper and lower annuli 63, 65.

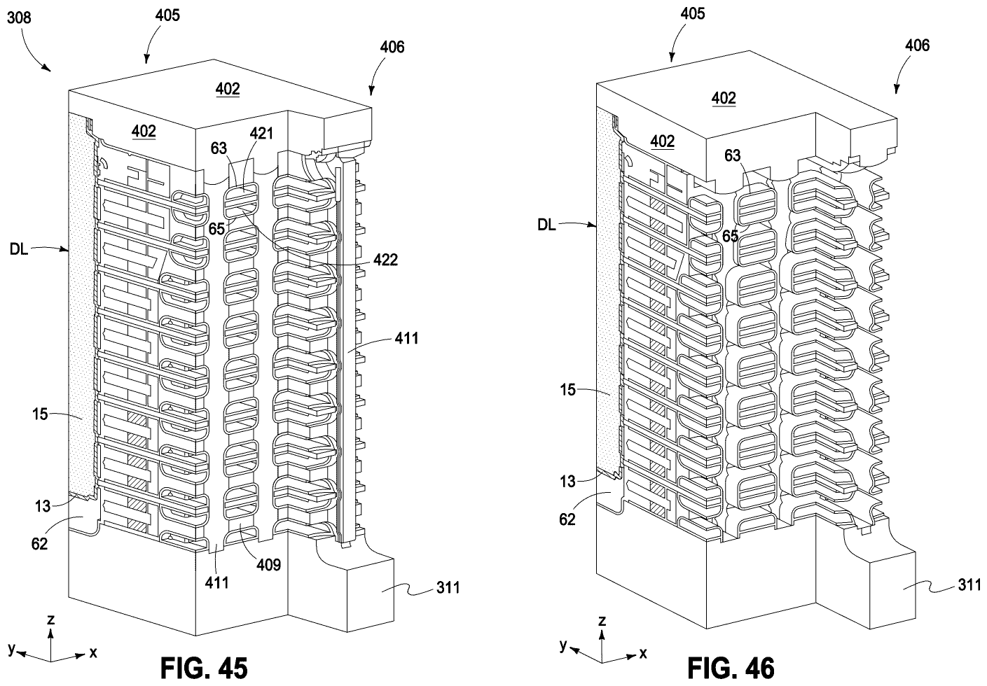

FIG. 45 shows removal of silicon nitride 407 that was radially internally within upper and lower annuli 63, 65. FIG. 46 shows some of materials 411 and 409 as having been removed sufficiently to expose outer surfaces of upper and lower annuli 63, 65 (e.g., such “some” having been surrounding sacrificial material 409 and 411 referred to above).

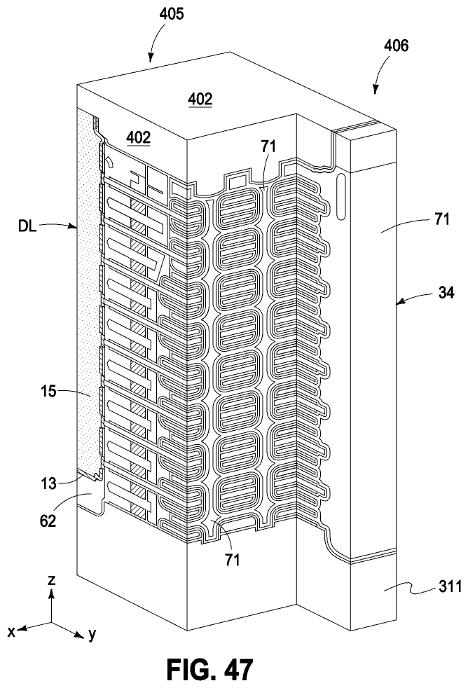

FIG. 47 shows subsequent processing wherein, as completely numerically designated in FIGS. 1-10, capacitor insulator 36 has been formed to comprise an upper ring 78 inside upper annulus 63, a lower ring 79 inside lower annulus 65, and an outer ring 81 that is collectively about upper annulus 63, lower annulus 65, mid-portion material 60, upper ring 78, and lower ring 79. Subsequently, common electrode 34 has been formed to comprise upper portion 74 inside upper annulus 63, lower portion 75 inside lower annulus 65, and an intervening portion 77 radially outside of outer ring 81 and that is vertically between immediately-vertically-adjacent memory cells MC. In one embodiment and as shown, after forming the intervening portion 77, conducting material 71 is formed directly against intervening portion 77 laterally between immediately-laterally-adjacent memory cells M C.

Any other attribute(s) or aspect(s) as shown and/or described herein with respect to other embodiments may be used.

Example embodiments as shown and described herein may provide good memory cell capacitance, more consistent distance between transistor and capacitor, and minimize memory cell-to-memory cell disturb.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The storage-node electrode comprises a mid-portion on and about the axis. An overlying portion is directly electrically coupled with and directly above the mid-portion. The overlying portion comprises an upper annulus in a vertical cross-section that is horizontally-elongated orthogonal to the axis. An underlying portion is directly electrically coupled with and directly below the mid-portion. The underlying portion comprises a lower annulus in the vertical cross-section. The common electrode in the vertical cross-section comprises an upper portion inside the upper annulus and a lower portion inside the lower annulus. The capacitor insulator in the vertical cross-section comprises an upper ring inside the upper annulus and about the upper portion. A lower ring is inside the lower annulus and about the lower portion. An outer ring is collectively about the upper annulus, the lower annulus, the mid-portion, the upper ring, the upper portion, the lower ring, and the lower portion.

In some embodiments, memory circuitry comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The storage-node electrode comprises a mid-portion on and about the axis. An overlying portion is directly electrically coupled with and directly above the mid-portion. The overlying portion comprises an upper annulus in a vertical cross-section that is horizontally-elongated orthogonal to the axis. An underlying portion is directly electrically coupled with and directly below the mid-portion. The underlying portion comprises a lower annulus in the vertical cross-section. The common electrode in the vertical cross-section comprises an upper portion inside the upper annulus and a lower portion inside the lower annulus. The capacitor insulator in the vertical cross-section comprises an upper ring inside the upper annulus and about the upper portion. A lower ring is inside the lower annulus and about the lower portion. An outer ring is collectively about the upper annulus, the lower annulus, the mid-portion, the upper ring, the upper portion, the lower ring, and the lower portion. The common electrode comprises an intervening portion that is vertically between immediately-vertically-adjacent of the memory cells. The capacitor insulator is vertically between the intervening portion and each of (a) and (b), where: (a): the underlying portion of an upper of the immediately-vertically-adjacent memory cells; and (b): the overlying portion of a lower of the immediately-vertically-adjacent memory cells, In the vertical cross-section the mid-portion has laterally-opposing edges. Conductive material is contiguous with conducting material of the upper and lower annuli and extends laterally over and aside the edges. The mid-portion has a mid-end on the axis. The overlying portion and the underlying portion individually comprise a sideways container that faces horizontally away from the horizontal transistor in a vertical cross-section that is through and horizontally-elongated along the axis. The overlying portion has a lowest far-end that is directly above the axis. The underlying portion has an uppermost far-end that is directly above the axis. The lowest and uppermost far-ends are laterally-spaced from the mid-end towards the horizontal transistor.

In some embodiments, a method is used in forming memory circuitry that ultimately comprises vertically-stacked memory cells individually comprising a horizontal transistor and a capacitor electrically coupled therewith. The capacitor and horizontal transistor are horizontally spaced relative one another along an axis. The capacitor comprises a storage-node electrode, a common electrode that is common to a plurality of the capacitors of the memory cells, and a capacitor insulator between the storage-node and common electrodes. The method comprises forming mid-portion material of the storage-node electrode on and about the axis within a cavity in surrounding sacrificial material. The cavity comprises an upper part directly above the mid-portion material and a lower part directly below the mid-portion material. A conductive upper annulus is formed in the upper part of the cavity directly against the mid-portion material and a conductive lower annulus in the lower part of the cavity directly against the mid-portion material. After forming the conductive upper and lower annuli, the sacrificial material is removed. After the removing, the capacitor insulator is formed to comprise an upper ring inside the upper annulus, a lower ring inside the lower annulus, and an outer ring that is collectively about the upper annulus, the lower annulus, the mid-portion material, the upper ring, and the lower ring. After forming the capacitor insulator, the common electrode is formed to comprise an upper portion inside the upper annulus, a lower portion inside the lower annulus, and an intervening portion radially outside of the outer ring and that is vertically between immediately-vertically-adjacent of the memory cells.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Memory circuitry comprising:
vertically-stacked memory cells individually comprising a horizontal transistor and a capacitor electrically coupled therewith; the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes;
the storage-node electrode comprising:
a mid-portion on and about the axis;
an overlying portion directly electrically coupled with and directly above the mid-portion, the overlying portion comprising an upper annulus in a vertical cross-section that is horizontally-elongated orthogonal to the axis; and
an underlying portion directly electrically coupled with and directly below the mid-portion, the underlying portion comprising a lower annulus in the vertical cross-section;
the common electrode in the vertical cross-section comprising an upper portion inside the upper annulus and a lower portion inside the lower annulus; and
the capacitor insulator in the vertical cross-section comprising:
an upper ring inside the upper annulus and about the upper portion;
a lower ring inside the lower annulus and about the lower portion; and
an outer ring collectively about the upper annulus, the lower annulus, the mid-portion, the upper ring, the upper portion, the lower ring, and the lower portion.

2. The memory circuitry of claim 1 wherein,
the common electrode comprises an intervening portion that is vertically between immediately-vertically-adjacent of the memory cells; and
the capacitor insulator being vertically between the intervening portion and each of (a) and (b), where:
(a): the underlying portion of an upper of the immediately-vertically-adjacent memory cells; and
(b): the overlying portion of a lower of the immediately-vertically-adjacent memory cells.

3. The memory circuitry of claim 1 wherein, in the vertical cross-section, the mid-portion has laterally-opposing edges, conductive material that is contiguous with conducting material of the upper and lower annuli and extending laterally over and aside the edges.

4. The memory circuitry of claim 1 wherein the mid-portion has an end on the axis, the capacitor insulator being laterally over and aside the mid-portion end.

5. The memory circuitry of claim 4 wherein the common electrode is laterally over and aside the end, the capacitor insulator being laterally between the end and the common electrode.

6. The memory circuitry of claim 1 wherein,
the mid-portion has a mid-end on the axis;
the overlying portion has a lowest far-end that is directly above the axis;
the underlying portion has an uppermost far-end that is directly above the axis; and
the lowest and uppermost far-ends being laterally-spaced from the mid-end towards the horizontal transistor.

7. The memory circuitry of claim 1 wherein the overlying portion and the underlying portion individually comprise a sideways container that faces horizontally away from the horizontal transistor in a vertical cross-section that is through and horizontally-elongated along the axis.

8. The memory circuitry of claim 7 wherein,
the mid-portion has a mid-end on the axis;
the overlying portion has a lowest far-end that is directly above the axis;
the underlying portion has an uppermost far-end that is directly above the axis; and
the lowest and uppermost far-ends being laterally-spaced from the mid-end towards the horizontal transistor.

9. The memory circuitry of claim 1 wherein,
the mid-portion has an end on the axis;
the storage-node electrode comprises a connecting portion laterally over and aside the end in a vertical cross-section that is through and horizontally-elongated along the axis, the connecting portion being contiguous with the overlying and underlying portions; and
the capacitor insulator being laterally between the connecting portion and the common electrode.

10. The memory circuitry of claim 1 wherein the mid-portion comprises a conductive metal silicide there-atop and there-below and that are respectively directly against the overlying portion and the underlying portion.

11. The memory circuitry of claim 10 wherein the mid-portion has an end on the axis, the silicide being laterally over and aside the mid-portion end.

12. Memory circuitry comprising:
vertically-stacked memory cells individually comprising a horizontal transistor and a capacitor electrically coupled therewith; the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes;
the storage-node electrode comprising:
a mid-portion on and about the axis;
an overlying portion directly electrically coupled with and directly above the mid-portion, the overlying portion comprising an upper annulus in a vertical cross-section that is horizontally-elongated orthogonal to the axis; and
an underlying portion directly electrically coupled with and directly below the mid-portion, the underlying portion comprising a lower annulus in the vertical cross-section;
the common electrode in the vertical cross-section comprising an upper portion inside the upper annulus and a lower portion inside the lower annulus;
the capacitor insulator in the vertical cross-section comprising:
an upper ring inside the upper annulus and about the upper portion;
a lower ring inside the lower annulus and about the lower portion; and
an outer ring collectively about the upper annulus, the lower annulus, the mid-portion, the upper ring, the upper portion, the lower ring, and the lower portion;
the common electrode comprising an intervening portion that is vertically between immediately-vertically-adjacent of the memory cells;
the capacitor insulator being vertically between the intervening portion and each of (a) and (b), where:
(a): the underlying portion of an upper of the immediately-vertically-adjacent memory cells; and
(b): the overlying portion of a lower of the immediately-vertically-adjacent memory cells;
in the vertical cross-section:
the mid-portion has laterally-opposing edges, conductive material that is contiguous with conducting material of the upper and lower annuli and extending laterally over and aside the edges;
the mid-portion has a mid-end on the axis;
the overlying portion and the underlying portion individually comprise a sideways container that faces horizontally away from the horizontal transistor in a vertical cross-section that is through and horizontally-elongated along the axis;
the overlying portion has a lowest far-end that is directly above the axis;
the underlying portion has an uppermost far-end that is directly above the axis; and
the lowest and uppermost far-ends being laterally-spaced from the mid-end towards the horizontal transistor.

13. A method used in forming memory circuitry, the memory circuitry ultimately comprising vertically-stacked memory cells individually comprising a horizontal transistor and a capacitor electrically coupled therewith; the capacitor and horizontal transistor being horizontally spaced relative one another along an axis; the capacitor comprising a storage-node electrode, a common electrode that is common to a plurality of the capacitors of the memory cells, and a capacitor insulator between the storage-node and common electrodes; the method comprising:
forming mid-portion material of the storage-node electrode on and about the axis within a cavity in surrounding sacrificial material, the cavity comprising an upper part directly above the mid-portion material and a lower part directly below the mid-portion material;
forming a conductive upper annulus in the upper part of the cavity directly against the mid-portion material and a conductive lower annulus in the lower part of the cavity directly against the mid-portion material;
after forming the conductive upper and lower annuli, removing the sacrificial material;
after the removing, forming the capacitor insulator to comprise:
an upper ring inside the upper annulus;
a lower ring inside the lower annulus; and
an outer ring that is collectively about the upper annulus, the lower annulus, the mid-portion material, the upper ring, and the lower ring; and
after forming the capacitor insulator, forming the common electrode to comprise an upper portion inside the upper annulus, a lower portion inside the lower annulus, and an intervening portion radially outside of the outer ring and that is vertically between immediately-vertically-adjacent of the memory cells.

14. The method of claim 13 wherein the mid-portion material has laterally-opposing edges in the cavity, and further comprising:
when forming the conductive upper and lower annuli, forming conductive material thereof to extend laterally over and aside the edges.

15. The method of claim 13 wherein the mid-portion material at least predominantly comprises silicon, the forming of the upper and lower annuli comprising:
forming conductive metal-material in the upper and lower parts of the cavity directly against the silicon; and
annealing the conductive metal-material and the silicon to form a conductive metal silicide directly against the silicon.

16. The method of claim 15 wherein,
the mid-portion has an end on the axis that comprises the silicon;
the conductive metal-material is formed directly against the silicon on the end; and
the annealing forming conductive metal silicide laterally aside and directly against the silicon on the end.

17. The method of claim 16 wherein the mid-portion material has laterally-opposing edges in the cavity, and further comprising:
when forming the conductive upper and lower annuli, forming conductive material thereof to extend laterally over and aside the edges.

18. The method of claim 13 wherein the sacrificial material at least predominantly comprises a silicon-germanium alloy and the mid-portion material at least predominantly comprises elemental-form silicon.

19. The method of claim 13 wherein,
the upper portion completely fills internal volume of the upper annulus; and
the lower portions completely fills internal volume of the lower annulus.

20. The method of claim 13 comprising, after forming the intervening portion, forming conducting material directly against the intervening portion laterally between immediately-laterally-adjacent of the memory cells.
